(19) United States
(12) Patent Application Publication
(10) Pub. No.: US 2013/0161502 A1
(43) Pub. Date: Jun. 27, 2013

(54) METHOD FOR ANALYSIS OF THE CHEMICAL COMPOSITION OF THE HEAVY FRACTION OF PETROLEUM

(71) Applicants: Andrew E. Pomerantz, Lexington, MA (US); Oliver C. Mullins, Ridgefield, CT (US)

(72) Inventors: Andrew E. Pomerantz, Lexington, MA (US); Oliver C. Mullins, Ridgefield, CT (US)

(73) Assignee: Schlumberger Technology Corporation, Sugar Land, TX (US)

(21) Appl. No.: 13/697,322

(22) PCT Filed: Mar. 5, 2011
(86) PCT No.: PCT/IB2011/050937

§ 371 Date: Feb. 28, 2013

Related U.S. Application Data
(60) Provisional application No. 61/333,889, filed on May 12, 2010.

(51) Int. Cl. H01J 49/00; G01R 33/46; G01N 23/083; G01V 9/00

(52) U.S. Cl. CPC H01J 49/0031; G01V 9/00; G01R 33/46; G01N 23/083
USPC 250/255; 250/282; 324/309; 378/53

(57) ABSTRACT

The chemical composition of petroleum samples is measured using orbitrap mass spectrometry with electrospray ionization (ESI). The orbitrap measurement is used in a screening to determine if one or more higher resolution (but more expensive) compositional analyses are justified.

### CROSS-REFERENCE TO RELATED APPLICATIONS

The present application claims priority from U.S. Provisional Application 61/333,889, filed May 12, 2010, which is incorporated herein by reference in its entirety.

### BACKGROUND OF THE INVENTION

1. Field of the Invention

The present invention relates to methods and apparatus for characterizing petroleum fluids extracted from a hydrocarbon-bearing geological formation.

2. Description of Related Art

Petroleum consists of a complex mixture of hydrocarbons of various molecular weights, plus other organic compounds. The exact molecular composition of petroleum varies widely from formation to formation. The proportion of hydrocarbons in the mixture is highly variable and ranges from as much as 97 percent by weight in the lighter oils to as little as 50 percent in the heavier oils and bitumens. The hydrocarbons in petroleum are mostly alkanes (linear or branched), cycloalkanes, aromatic hydrocarbons, or more complicated chemicals like asphaltenes. The other organic compounds in petroleum typically contain carbon dioxide (CO₂), nitrogen, oxygen, and sulfur, and trace amounts of metals such as iron, nickel, copper, and vanadium.

Petroleum is usually characterized by SARA fractionation where asphaltenes are removed by precipitation with a paraffinic solvent and the deasphalted oil separated into saturates, aromatics, and resins by chromatographic separation.

The saturates include alkanes and cycloalkanes. The alkanes, also known as paraffins, are saturated hydrocarbons with straight or branched chains which contain only carbon and hydrogen and have the general formula CₙH₂ₙ₊₂. They generally have from 5 to 40 carbon atoms per molecule, although trace amounts of shorter or longer molecules may be present in the mixture. The alkanes include methane (CH₄), ethane (C₂H₆), propane (C₃H₈), i-butane (iC₄H₁₀), n-butane (nC₄H₁₀), i-pentane (iC₅H₁₂), n-pentane (nC₅H₁₂), hexane (C₆H₁₄), heptane (C₇H₁₆), octane (C₈H₁₈), nonane (C₉H₂₀), ^{decane} (C₁₀H₂₂), hendecane (C₁₁H₂₄)—also referred to as endecane or undecane, dodecane (C₁₂H₂₆), tridecane (C₁₃H₂₈), tetradecane (C₁₄H₃₀), pentadecane (C₁₅H₃₂) and hexadecane (C₁₆H₃₄). The cycloalkanes, also known as napthenes, are saturated hydrocarbons which have one or more carbon rings to which hydrogen atoms are attached according to the formula CₙH₂ₙ. Cycloalkanes have similar properties to alkanes but have higher boiling points. The cycloalkanes include cyclopropane (C₃H₆), cyclobutane (C₄H₈), cyclopentane (C₅H₁₀), cyclohexane (C₆H₁₂), and cycloheptane (C₇H₁₄).

The aromatic hydrocarbons are unsaturated hydrocarbons which have one or more planar six carbon rings, called benzene rings, to which hydrogen atoms are attached with the formula CₙHₙ. They tend to burn with a sooty flame, and many have a sweet aroma. The aromatic hydrocarbons include benzene (C₆H₆) and derivatives of benzene, as well as polyaromatic hydrocarbons.

Resins are the most polar and aromatic species present in deasphalted oil and, it has been suggested, contribute to the enhanced solubility of asphaltenes in crude oil by solvating the polar and aromatic portions of the asphaltenic molecules and aggregates.

Asphaltenes are insoluble in n-alkanes (such as n-pentane or n-heptane) and soluble in toluene. The C:H ratio is approximately 1:1.2, depending on the asphaltene source. Unlike most hydrocarbon constituents, asphaltenes typically contain a few percent of other non-carbon atoms (called heteroatoms) that replace carbon in the backbone of the molecular structure. Typical heteroatoms include nitrogen, oxygen, sulfur, phosphorus, boron, chlorine, bromine, iodine, vanadium, and nickel. Heavy oils and tar sands contain much higher proportions of asphaltenes than do medium API oils or light oils. Condensates are virtually devoid of asphaltenes. As far as asphaltene structure is concerned, experts agree that some of the carbon and hydrogen atoms are bound in ring-like, aromatic groups, which also contain the heteroatoms. Alkane chains and cyclic alkanes contain the rest of the carbon and hydrogen atoms and are linked to the ring groups. Within this framework, asphaltenes exhibit a range of molecular weight and composition. Asphaltenes have been shown to have a distribution of molecular weight in the range of 300 to 1400 g/mol with an average of about 750 g/mol. This is compatible with a molecule containing seven or eight fused aromatic rings, and the range accommodates molecules with four to ten rings. It is also known that asphaltene molecules aggregate to form nanoaggregates and clusters.

Non-movable bitumen (pyrobitumen, migrabitumen, gilsonite, and tar, for example) occurs in carbonate and siliciclastic oil and gas reservoirs in many basins throughout the world. Such non-movable bitumen includes a high fraction of asphaltenes and can be formed from petroleum in the reservoir through natural or artificial alteration processes such as thermal cracking of oil (pyrobitumen), gas deasphalting of oil (asphaltene precipitation), or by inspissation, water washing, or oxidation (tar). Non-movable bitumen acts as a flow barrier to hydrocarbons and thus can contribute to compartmentalization of the reservoir fluids. Reservoir compartmentalization can significantly hinder production of fluids from the reservoir and can make the difference between an economically-viable field and an economically-nonviable field. The impact of the non-movable bitumen on production depends upon the type, solubility, and mechanism of formation of the non-movable bitumen, and the volume and distribution of the non-movable bitumen in the reservoir.

Techniques that aid an operator in accurately describing reservoir compartments and their distribution can increase understanding of such reservoirs and ultimately raise production. Conventionally, reservoir architecture has been determined utilizing pressure-depth plots and pressure gradient analysis with traditional straight-line regression schemes. This process may, however, be misleading as fluid compositional changes and compartmentalization give distortions in the pressure gradients, which result in erroneous interpretations of fluid contacts or pressure seals. Additionally, pressure communication does not prove flow connectivity.

Non-movable tar deposits, which are commonly referred to as tar mats, are present in many oil reservoirs throughout the world and are quite common in carbonate reservoirs in the Middle East. Tar mats are usually—but not always—located at or near present-day oil/water contacts. In these reservoirs, it is common to inject water at or near the tar mat in order to maintain reservoir pressure during production. In these scenarios, understanding the mechanism of formation of the non-movable tar mat as well as the volume and distribution of the non-movable tar mat in the reservoir can aid in optimizing the desired effect of the water injection while minimizing the loss of oil that can result from such processes.

The chemical composition of crude oil influences many properties of oil that are of central importance to exploration and production. However, there exists no single instrument capable of measuring the extremely complex petroleum composition. Most chemical analyses of petroleum focus on gas chromatographic (GC) techniques, which probe the composition of the light fraction of petroleum. The heavy ends (including asphaltenes) are not detected by GC techniques, but influence several important properties of the petroleum, such as fluid viscosity, rock wettability, tar mats, flow assurance, emulsion stability, and upgrading/refining requirements. Although measurements of the concentration of asphaltenes in crude oil and measurements of the conditions under which asphaltene precipitation/deposition occur are commonplace, those measurements offer no information about the chemical composition of asphaltenes and thus are of limited utility. Few measurements of the composition of asphaltenes exist. Perhaps the most informative is Fourier transform ion cyclotron resonance mass spectrometry (FTICR-MS). The high resolution and accuracy of this technique make it capable of resolving and identifying the molecular formulas of thousands of components of petroleum, and it can be carried out in a manner that is sensitive to heavy compounds. However, the associated instrument is expensive, difficult to maintain, and can produce errors if not operated correctly. For example, if inappropriate ionization techniques (such as some versions of laser desorption/ionization) are employed, aggregate ions (instead of molecular ions) can be formed. Additionally, if the mass spectrum is improperly calibrated, assignments of molecular formulas can be incorrect. Hence, FTICR-MS is too expensive to be performed on all petroleum samples.

### BRIEF SUMMARY OF THE INVENTION

It is therefore an object of the invention to provide methods and apparatus that accurately characterize compositional components of petroleum samples collected at varying locations in a reservoir in order to allow for accurate reservoir analysis, particularly for heavy fractions of petroleum.

In accord with the invention, a method is provided for characterizing a hydrocarbon reservoir of interest traversed by a wellbore. The method includes performing laboratory fluid analysis on petroleum samples obtained from downhole fluid sampling operations at well-defined locations within a reservoir (and/or on petroleum samples extracted from core samples obtained from well-defined locations within the reservoir) to measure the chemical composition of the heavy fraction of such petroleum samples. In accord with one preferred method, the workflow includes first collecting petroleum samples from well-defined locations in the reservoir. After the petroleum samples are collected, they are preferably verified as being representative reservoir fluids using different versions of downhole fluid analysis (DFA). In addition, it is preferred that the petroleum samples be verified as not being substantially altered during transportation to the laboratory using a chain of custody.

The chemical composition of the petroleum samples is then first characterized using orbitrap mass spectrometry. The results of the orbitrap mass spectroscopy function as a proxy measurement of the composition of the heavy fraction of the analyzed petroleum sample. The orbitrap proxy measurement is then used in a screening step to determine if a more comprehensive but more expensive alternative chemical composition analysis is justified. When justified, the chemical compositions of the petroleum samples are then characterized using a higher-resolution chemical composition analysis. In a preferred embodiment, the orbitrap measurement is used as a proxy measurement for the higher resolution Fourier transform ion cyclotron resonance mass spectrometry (FTICR-MS).

Additional objects and advantages of the invention will become apparent to those skilled in the art upon reference to the detailed description taken in conjunction with the provided figures.

### BRIEF DESCRIPTION OF THE DRAWINGS

FIG. 1 is a schematic diagram of an exemplary workflow for petroleum reservoir analysis according to the present invention.

FIG. 2 is a flowchart of a lab compositional analysis step of the workflow of FIG. 1.

FIG. 3 is a graph illustrating comparative results of heteroatom class distributions obtained from orbitrap spectrometry using electrospray ionization (ESI) relative to Fourier transform ion cyclotron resonance mass spectrometry (FTICR-MS) for a petroleum fluid sample.

### DETAILED DESCRIPTION OF THE INVENTION

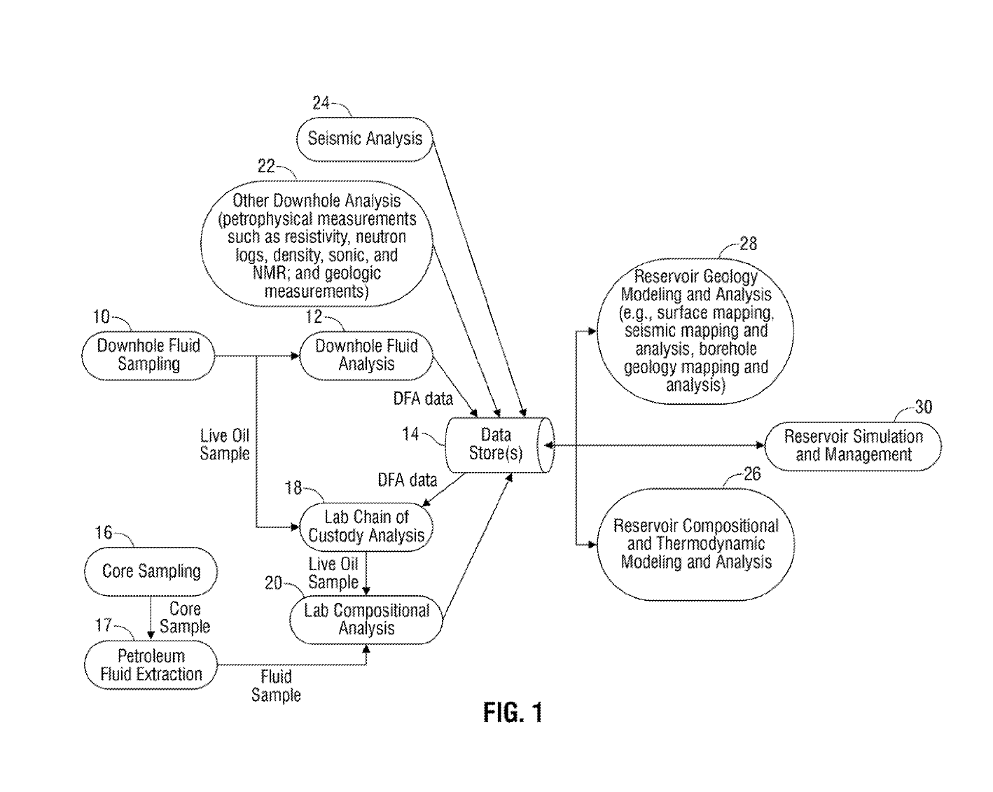

FIG. 1 illustrates an exemplary workflow for petroleum reservoir analysis according to the present invention, although the workflow may include only a portion of what is shown and now described, or may include additional steps.

Initially, petroleum fluid samples are collected by some means. By way of example, petroleum fluid samples may be collected by downhole fluid sampling, by core extraction, or by a combination of both such methods. Where fluid samples are collected by downhole fluid sampling, in stage 10 a downhole fluid sampling tool is deployed within a wellbore traversing a reservoir of interest and operated to extract from well-defined locations and store one or more live oil samples within the tool. The downhole fluid sampling tool is preferably a dynamical testing tool, such as the MDT tool available from Schlumberger Technology Corporation of Sugar Land, Tex., USA. Optionally, but in accord with preferred petroleum fluid collection practices, at stage 12, a downhole fluid analysis tool, which can be the same tool used for downhole fluid sampling or a separate tool, is deployed within the wellbore traversing the reservoir of interest and operated to extract live oil fluid from the formation adjacent the wellbore and perform downhole fluid analysis of the live oil fluid. The downhole fluid analysis derives properties (e.g., gas-oil ratio (GOR), oil-based mud contamination, saturation pressure, live fluid density, live fluid viscosity, and compositional component concentrations) that characterize the live oil fluid at the pressure and temperature of the formation. The fluid properties measured by downhole fluid analysis in stage 12, together with other sample data (e.g., sample number, date of acquisition, depth, and tool configuration data) are stored as DFA data in data store 14. The data store 14 is preferably realized as a central unitary database that contains sampling logs, transfer and shipping information, and all downhole, wellsite, field, and laboratory measurements. Such a unitary design provides several functions including management of access and reporting, as well as data transfer to modeling and analysis applications (stages 26, 28, 30). Alternately, the data store 14 can be realized by a plurality of database systems where data of interest is transferred between databases by electronic communication or other means.

Where petroleum fluids are provided by core extraction, at stage 16, a coring tool is deployed within the wellbore traversing the reservoir of interest and operated to extract one or more core samples from the formation. There are several types of core samples that can be recovered from the wellbore, including full-diameter cores, oriented cores, native state cores, and sidewall cores, which may be acquired as the well is being drilled or thereafter. In one embodiment, the coring tool obtains one or more sidewall cores from the formation adjacent the wellbore. An example of a commercially available coring tool of this type is the Mechanical Sidewall Coring Tool (MSCT) available from Schlumberger Technology Corporation. The MSCT employs a hollow coring bit that is deployed in a configuration where it extends generally transverse to the borehole axis. The hollow coring bit is mechanically rotated relative to the tool housing. The coring bit may be extended into the formation as the bit rotates, thereby capturing a sidewall core within the hollow interior of the coring bit. The MSCT is further described in U.S. Pat. Nos. 4,714,119 and 5,667,025. Another example of a commercially available sidewall coring tool is the Chronological Sample Taker (CST) also available from Schlumberger Technology Corporation. The CST employs explosive charges to fire hollow cylindrical bullets into the formation at desired sample depths. U.S. Pat. Nos. 2,928,658; 2,937,005; 2,976,940; 3,003,569; 3,043,379; 3,080,005; and 4,280,568 disclose various types and aspects of explosive-type sidewall coring tools. The coring tool can be run in combination with a gamma ray tool (or other suitable logging tool) to correlate with openhole logs for accurate, real-time depth control of the coring points. Each core sample is isolated and identified from other core samples. All petroleum samples acquired, i.e., whether live oil samples collected in stage 10 or the core samples collected in stage 16, are assigned sample numbers and validated at the wellsite and transported to a laboratory for analysis.

Optionally, but in accord with a preferred embodiment of the method, at stage 18, the downhole fluid analysis measurements are reproduced in the laboratory for chain of custody analysis. More specifically, the live oil sample is reconditioned to the formation reservoir temperature and pressure at the sample depth (as dictated by the DFA data stored in the data store 14). The reconditioned live oil sample is then subjected to analytical measurements (e.g., GOR, oil-based mud contamination, and fluid composition) that replicate the downhole fluid analysis measurements, and the results of the laboratory measurements are compared to the results of the corresponding downhole measurements stored as part of the DFA data in data store 14. If there is agreement between the downhole and laboratory fluid measurements, the chain of custody is verified. If there is disagreement between the downhole and laboratory fluid measurements, the chain of custody verification fails and the sample and the laboratory measurements based thereon can be discarded or otherwise ignored. In the case of failure, actions can be taken to identify and correct the cause of the failure, which can arise from hardware failure of the downhole fluid analysis tool or laboratory tool, and inappropriate sampling, sample reconditioning, and/or sample transfer techniques. A preferred chain of custody analysis for the fluid samples is described in detail in U.S. Pat. No. 7,158,887, which is incorporated by reference herein in its entirety.

In stage 20, live oil sample(s), preferably whose chain of custody has been verified, are subjected to compositional analysis in the laboratory, and the results of the analysis can be stored in the data store 14. From these measurements, detailed information on the chemical composition of the petroleum of the live oil sample(s) can be determined, enabling more confident reservoir characterization. Moreover, other laboratory compositional and property analysis can be performed on the live oil sample as desired.

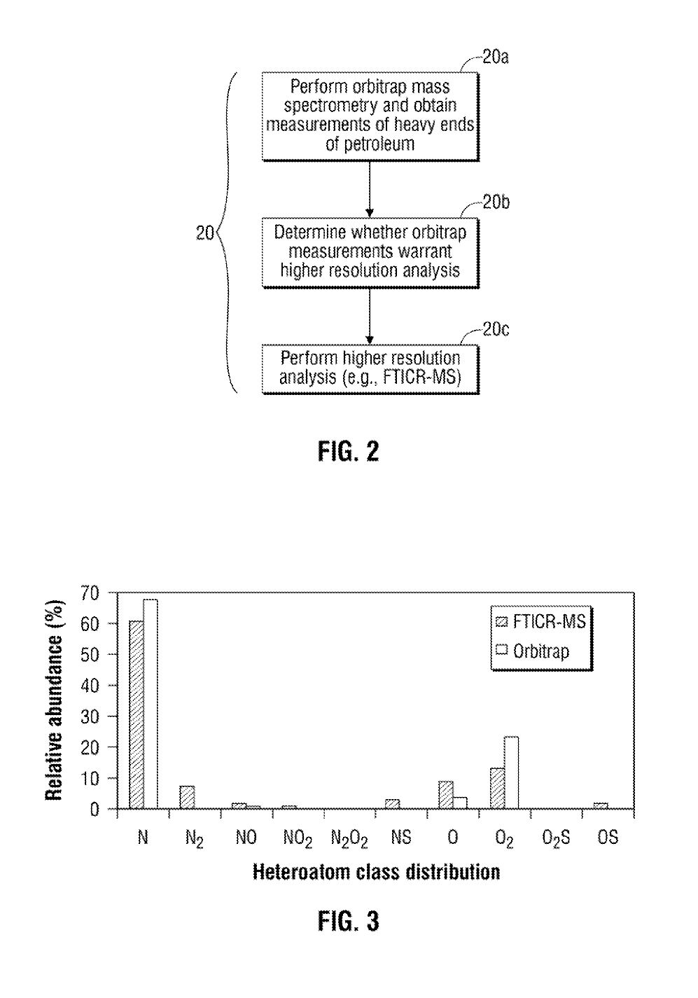

Referring to FIG. 2, in the preferred methodology for compositional analysis, an orbitrap mass spectrometer is used at 20a to provide a first characterization of the chemical composition of the petroleum sample. The orbitrap device can effectively measure the heavy fraction of the petroleum sample (including the high molecular weight components including resins and asphaltenes that can be part of the petroleum sample). The orbitrap mass spectrometer is based on an electrostatic ion trap mass analyzer and employs an outer barrel-like electrode and a coaxial inner spindle-like electrode that form an electrostatic field with quadro-logarithmic potential distributions. Ions are injected tangentially into the electric field between the electrodes and trapped because their electrostatic attraction to the inner electrode is balanced by centrifugal forces. Thus, ions cycle around the inner electrode in rings. In addition, the ions also move back and forth along the axis of the inner electrode. Therefore, ions of a specific mass-to-charge ratio move in rings which oscillate along the inner electrode. The frequency of these harmonic oscillations is independent of the ion velocity and is inversely proportional to the square root of the mass-to-charge ratio (m/z or m/q). By sensing the ion oscillation (which is similar to Fourier transform ion cyclotron resonance mass spectrometry (FTICR-MS) utilizing a Penning trap), the orbitrap device can be used as a mass analyzer. However, because an orbitrap device does not necessitate a magnetic field, it is much less expensive and easier to maintain and operate relative to a FTICR-MS device. A linear ion trap can be used as a front end for the orbitrap device. Such an orbitrap device is available as the LTQ Orbitrap Discovery product line distributed commercially by Thermo Fisher Scientific Inc. of Waltham, Mass., USA.

An orbitrap device operated under the stated conditions has a relatively high mass accuracy (1-2 ppm), a relatively high resolving power (generally 100,000, and up to above 200,000) and a high dynamic range (around 5000). Nevertheless, it is commonly believed that the resolution of the orbitrap device is insufficient to resolve the components of petroleum based on their molecular weight. However, in accord with the invention, it is recognized that the orbitrap device can be operated in a manner that sufficiently resolves the heavy fraction of a petroleum sample under test such that conclusions from the orbitrap measurements are similar to conclusions that can be derived from a higher resolution chemical composition analysis, such as from FTICR-MS.

In order to operate the orbitrap at a resolution sufficient to serve as a proxy measurement of the composition of the heavy fraction of a petroleum sample under test, it is preferable that electrospray ionization (ESI) be used. Almost all mass spectrometers are sensitive only to ionized species, hence, the sample must be ionized prior to mass analysis. ESI is a well known ionization technique that ionizes only the polar compounds in petroleum. Polar compounds are found almost exclusively in the heavy fraction of petroleum, so an ESI-based measurement is sensitive to the heavy fraction of the petroleum sample under test. As the light fraction of petroleum (including the alkanes and cycloalkanes) are non-polar compounds, ESI does not ionize the light fraction of petroleum, and the ESI-based measurement is insensitive to the light fraction of the petroleum sample under test. However, the selective ionization of polar compounds means that the mass spectrum resulting from ESI is less complex than the mass spectrum resulting from techniques that ionize both polar and non-polar compounds, such as photoionization. The performance of the orbitrap using ESI is sufficient to resolve and identify the most abundant compounds in the heavy fraction of the petroleum sample under test.

In accord with a preferred manner of operating the orbitrap device, the “apodization” feature of the device is disabled. Apodization is a method of signal processing that results in an improved signal-to-noise ratio. Apodization is used in the orbitrap device by default, as it generally improves the performance of the device. However, in accord with a preferred mode of operation of the orbitrap device, the apodization feature is disabled. While this results in a lower signal-to-noise ratio, it has been found to provide an improved resolution of the compounds in the heavy fraction of petroleum samples.

FIG. 3 shows a mass spectrum of an exemplary petroleum sample measured by an orbitrap device with ESI together with a mass spectrum of the same petroleum sample measured with FTICR-MS and ESI at a 9.4 T magnetic field strength. In both cases, only negatively charged ions were analyzed. This figure shows the heteroatom class distribution from each measurement. The heteroatom class distribution shows the relative abundance of a number of compounds with combinations of heteroatoms that are contained within the heavy fractions of petroleum (e.g., compounds with combinations of nitrogen, oxygen, and sulphur heteroatoms).

More particularly, the heteroatom class distributions are derived from the measured mass spectrum in the orbitrap device with ESI. To that end, the orbitrap measures the molecular weight of molecules with a very high accuracy, on par with FTICR-MS. Because the measured molecular weights distinctly describe discrete combinations of atoms, the measured molecular weight determines the molecular formulas of the molecules in the same. The molecular weight of carbon (C) is 12.0000, the molecular weight of nitrogen (N) is 14.00307, and the molecular weight of oxygen (O) is 15.99491. By way of example, if it is known that a molecule contains no more than elements of C, N, and O, and the measured molecular weight of the molecule is 27.99491, the one and only combination to obtain that molecular weight is one C atom and one O atom. Therefore, the molecule must have the molecular formula CO.

Assuming that the same information was desired, but no orbitrap or FTICR-MS is available, an instrument with lower mass accuracy would need to be used. Then, the measured mass of the same of molecule (CO) would be measured as 28.0; that is, because of the limited accuracy of the alternate method, the extra significant digits are not obtained. However, a measured mass of 28.0 can be CO or N₂, so with a lower accuracy instrument and method, the molecular formula is indeterminate. It has been conventional knowledge that FTICR-MS was the only mass spectrometer with sufficient accuracy to provide all the significant digits in a mass measurement required to ascertain a molecular formula with certainty. However, it has now been determined that the orbitrap with ESI, used in accord with the invention, provides the same accuracy of information in a substantially less expensive manner than FTICR-MS for purposes of measuring the molecular weight of the components of the heavy fraction of petroleum.

Petroleum molecules are made of five different elements: C (carbon), N (nitrogen), O (oxygen), H (hydrogen), and S (sulfur). Using the method described above, the molecular formula of many different components of petroleum can be measured with the orbitrap device. That is, the analysis of the petroleum fluid sample in the orbitrap device with ESI provides thousands of peaks in the mass spectrum. Each peak is assigned a molecular formula, written generically as C_{c}HₕNₙOₒSₛ, and a measure of the intensity of the peak. This results in a very large data set.

In order to reduce the data to a more manageable set, the heteroatom class distribution is used. Such class distribution reduces the data by summing the intensity of all peaks in a particular heteroatom class (constant value of n, o, and s, e.g., n=1, o=2, s=0, written “NO₂”) over any value of c and h. This sum is performed for each heteroatom class, and the result is the heteroatom class distribution. The heteroatom class distributions for orbitrap with ESI and FTICR-MS with ESI are identical, within the 0-20 percent error for relative abundance expected for ESI. Therefore, negative ion ESI orbitrap mass spectrometry is demonstrated to serve successfully as a proxy measurement of the composition of the heavy ends of petroleum, which at 20b is used as a screening tool to decide if a higher resolution, but more expensive compositional analysis, such as FTICR-MS, is justified.

Furthermore, while FIG. 3 shows the results of analyzing only the negative ions, it is appreciated that alternatively only the positive ions can be subjected to analysis. Moreover, the negative and positive ions can each be separately subjected to mass spectrometry with the orbitrap device using ESI. In order to analyze a particular set of charged ions, it is appreciated that the ions are in the gas phase and move around in an electric field. As opposite electric charges attract while like charges repel, a positive charge source can be positioned near the entrance to the analyzer, and a negative charge source can be positioned far from the entrance to the analyzer. This results in only the negative ions entering the analyzer. Similarly, the charge sources can be reversed, with the negative charge source positioned near the entrance to the analyser and the positive charge source located further from the entrance to the analyser to cause the positive ions to enter the analyzer and be subjected to the mass spectrum analysis. Either of such analyses can be performed, or both analyses may be separately performed and then considered separately or together to characterize the fluid sample.

The criteria at 20b for determining whether higher resolution compositional analysis is justified are situation specific. For example, if the orbitrap mass spectrometry of 20a results in a significant number of poorly resolved peaks over the class distribution of the relevant heteroatoms (e.g., nitrogen, oxygen, and sulphur-containing compounds), then it is determined in 20b that higher resolution compositional analysis is needed to determine the elemental compositions of the petroleum sample. Peaks are considered poorly resolved if they cannot be assigned to a molecular formula. By way of example, if the ionized sample contains CO, a peak at 27.99491 is expected. In addition, if the sample contains N₂, a peak at 28.00614 is expected. If the peaks are well resolved, two peaks are present, one at each mass. If the peaks are not well resolved, only one peak may be present at or near the average mass of two surrounding molecular masses—which would be 28.00053 for CO and N₂. When it is determined that no such molecule has a molecular weight of 28.00053, it is recognized that the peak is poorly resolved. Whether the number of poorly resolved peaks is significant depends on how the data is to be used. Generally, having the peaks resolved such that 99 percent of the peaks are assignable to a molecule is sufficient for very good results. However, depending on the circumstance, if greater than one percent, or greater than three percent, or greater than ten percent of the peaks are not assignable, such may be considered significant. It should be noted that only peaks with intensity above a set threshold are considered in this analysis. For example, if a small peak is observed, that peak might actually not be a real peak, but instead may be simply random noise. If the set of peaks includes many alleged peaks that are actually random noise, it will look like there are many poorly resolved peaks in that set. To avoid this problem, all peaks whose intensity is below a threshold intensity are disregarded. The threshold intensity can be selected in many ways, but typically it is selected by looking at the magnitude of typical random noise peaks in the data—the higher the typical random noise peaks are, the higher the threshold intensity should be.

By way of another example, if multiple petroleum samples are being studied, the orbitrap mass spectrometry results can be used to provide geochemical fingerprints of the chemical compositions of each one; e.g., based on the heteroatom class distribution. Petroleum samples with nearly identical fingerprints would not all require high resolution study, reducing the number of high resolution experiments required. By way of example, multiple petroleum samples, whether obtained at different times from a single location, different locations along a common downhole depth, or different locations at different downhole depths can be compared for matching fingerprints; i.e., corresponding or matching heteroatom class distributions. Where such fingerprints match, only one of the matching petroleum fluid samples needs to be studied with a higher resolution chemical analysis tool to determine the elemental compositions of all of the petroleum samples having matching fingerprints.

Examples of higher-resolution compositional analyses that can be used to further characterize a petroleum sample in 20c include:
Fourier transform ion cyclotron resonance mass spectrometry (FTICR-MS), including the use of various ionization techniques (such as electrospray ionization, atmospheric pressure chemical ionization, atmospheric pressure photoionization, and others) in conjunction with a magnetic field to measure the molecular weight of different components of crude oil to sufficient accuracy and precision that their molecular formulas can be determined;
X-ray absorption near edge spectroscopy (XANES), including carbon, nitrogen, and (especially) sulfur elements, which technique measures the local chemical environment around the measured element (for example, sulfur XANES measurements can determine the distribution of oxidation states of sulfur in petroleum);
X-ray Raman spectroscopy on carbon (XRS), which technique measures the way in which fused aromatic rings are connected; and
¹H, ¹³C, or ¹⁵N nuclear magnetic resonance spectroscopy (NMR), which measures the distribution of bonding environments in hydrogen, carbon, and nitrogen.
   From one or more of these high resolution measurements, more detailed information on the chemical composition of the petroleum of the fluid sample can be determined and stored in the data store 14, enabling more confident reservoir characterization.

The inherently high resolution of the higher-resolution compositional analysis of step 20c, particularly FTICR-MS which has a resolution of 450,000 at m/z=500 Th at common magnetic field strengths (such as 9.4 T), implies that any spectrum peaks unresolvable with the orbitrap mass spectrometry of 20a may be resolved with FTICR-MS. Additionally, FTICR-MS allows less selective ionization techniques (such as photoionization) to be employed, increasing the number of compounds detected. FTICR-MS also allows detection of compounds with difficult to resolve elements, such as metals. Hence, FTICR-MS provides more information than the orbitrap mass spectrometry of 20a.

Other techniques can be carried out, either before or after orbitrap mass spectrometry and, when justified, either before or after the higher resolution technique(s) to confirm or provide additional information with respect to the compositional analysis of the fluid sample including:
Gas chromatography, including gas chromatography with various detection schemes (flame ionization detector, thermal conductivity detector, mass spectrometer);
Saturates-aromatics-resins-asphaltenes (SARA) analysis;
Optical spectroscopy in the ultraviolet, visible, and near-infrared regions;
Infrared spectroscopy (including instruments using Fourier transform);
Fluorescence spectroscopy;
Raman spectroscopy;
Liquid chromatography, including various modifications (for example, high pressure/performance, reverse phase, and with mass spectrometric detection);
Pyrolysis experiments with gas chromatography or other detection methods; and
Isotope analysis (for example performed using an isotope ratio mass spectrometer).

In an embodiment, SARA analysis and/or NMR spectroscopy can also be carried out in a laboratory as part of stage 20. Such analysis is effective in characterizing the heavy fractions (including the high molecular weight components including resins and asphaltenes) that can be part of the extracted hydrocarbons.

If at stage 20 laboratory analysis is to be performed on core samples collected at stage 16, bulk measurements (e.g., porosity, grain density, permeability, and residual saturation) to measure properties of the core sample can be performed, and the results of the analysis can be stored in the data store 14. Furthermore, if the core sample includes movable hydrocarbons, hydrocarbon fluids are extracted from the core sample at 17. Such fluids may be extracted by centrifuging the core sample. In the case that the core sample is non-movable bitumen, hydrocarbon fluid can be extracted from the bitumen core sample using a solvent. In either case, the composition of the extracted hydrocarbon fluid can be analyzed by the geochemical analysis described above. That is, the petroleum fluid extracted from any core sample at 17 can also be analyzed by being subjected to a first chemical composition characterization using orbitrap mass spectrometry of 20a, and subject to justifying circumstances identified in 20b, then optionally subjected to a second higher resolution chemical composition characterization using, e.g., FTICR-MS, in 20c.

In stage 22, other downhole analyses can be performed within one or more wellbores that traverse the reservoir of interest. Such analyses can include petrophysical measurements (such as resistivity, neutron logs, density, sonic, borehole seismic and NMR) and geologic measurements. The results of such analyses are stored in the data store 14.

In stage 24, three-dimensional (and 4-D) subsurface seismic analysis of the reservoir of interest can be performed to collect seismic data that can be used to characterize the structure of the rock formations of the reservoir as well as characterize reservoir flow properties such as fracture density, porosity, and permeability distribution. The seismic data collected in stage 24 is stored in the data store 14.

In stage 26, the data that characterizes the compositions and other fluid properties of the reservoir fluids as derived from the downhole fluid analysis of stage 12 can be processed to model the compositions and thermodynamic (pressure-volume-temperature (PVT)) properties of the reservoir as a function of depth within the reservoir. Such analysis can be performed in real-time in conjunction with the downhole fluid analysis of stage 12 in order to provide guidance as to the accuracy and effectiveness of the downhole fluid analysis and make a decision as to whether additional downhole fluid analysis is necessary. Furthermore, the data characterizing the composition and fluid properties of the reservoir fluids stored in data store 14 (which is derived from the downhole fluid analysis of stage 12 and the laboratory analysis of stage 20 and possibly other analysis) can be processed off-line to model the compositions and thermodynamic (PVT) properties of the reservoir as a function of depth within the reservoir. The processing and analysis of stage 28 can predict incipient gas and liquid hydrate formation conditions in reservoir fluids and/or the thermodynamic precipitation point of waxes and asphaltenes with knowledge of reservoir fluid compositions. Module accuracy can be confirmed by laboratory testing. In an exemplary embodiment, PVT Pro simulation software, together with DBR SOLIDS and DBR Hydrate softwares, all of which are available from Schlumberger Canada Limited of Edmonton, Alberta, Canada, are used to carry out the compositional and thermodynamic modeling of stage 28. The compositional and thermodynamic model data generated in stage 28 is stored in data store 14.

In stage 28, the seismic data stored in the data store 14 (which is derived from the seismic analysis of stage 24), as well as the results of the petrophysical and geologic measurements of stage 22 as stored in the data store 14 can be processed to model, visualize, and analyze the geological structures of the reservoir of interest. Such modeling can involve surface mapping and seismic mapping and analysis, as well as borehole geology mapping and analysis as is well known in the arts. In an exemplary embodiment, the Geoframe, Geoviz and Petrel softwares available from Schlumberger Technology Corporation are used to carry out the reservoir modeling, visualization, and analysis of stage 26. The geological model data generated in stage 26 is stored in data store 14.

In stage 30, the geological model data stored in the data store 14 in stage 26 and/or the compositional and thermodynamic model data stored in the data store 14 in stage 28 can be used for analysis and management of the reservoir of interest.

For example, geological model data stored in the data store 14 in stage 26 and/or the compositional and thermodynamic model data stored in the data store 14 in stage 28 can be input to basin modeling software that models and visualizes the geological structures of the reservoir along with a record of the generation, migration, accumulation, and loss of oil and gas in the reservoir of interest over time. For example, PetroMod software available from Schlumberger Technology Corporation can be used for basin modeling as part of stage 30.

In another example, the geological model data stored in the data store 14 in stage 26 and/or the compositional and thermodynamic model data stored in the data store 14 in stage 28 can be used for planning and optimizing production from the reservoir of interest. Such data can be used to evaluate different production scenarios in order to optimize production efficiency and recovery. Moreover, the data can be input to reservoir simulators that provide for modeling and visualization of production scenarios in order to assist in the production decision making processing and optimizations thereof over time. For example, Eclipse software available from Schlumberger Technology Corporation can be used for reservoir simulation as part of stage 30.

In stage 30, preferably as part of basin modeling, the compositions (particularly the gas-insoluble fractions and possibly other fractions) of a non-movable bitumen core sample extract as stored in data store 14 in stage 20 are compared to the compositions of the live oil sample as stored in data store 14 in stages 12 and 20 to infer structure (or other properties) of the reservoir of interest. For example, petroleum samples taken from different locations within the reservoir that are determined to have substantially identical geochemical fingerprints can be assumed to be in fluid communication. That is, because the fluids have a common set of molecules in relatively the same abundance, it can be concluded that the petroleum fluid samples were obtained from portions of the reservoir having fluids that can flow or diffuse together. As the fingerprints of multiple samples are analyzed, an indication of the geochemical makeup of the composition of the reservoir is provided. Petroleum samples taken from different locations within the reservoir that are determined to have different geochemical fingerprints can be an indication that reservoir fluids are in a state of non-equilibrium due to real-time charging.

There have been described and illustrated herein a preferred embodiment of a method, system, and apparatus for downhole fluid analysis of a reservoir of interest and for characterizing the reservoir of interest based upon such downhole fluid analysis and follow on laboratory analysis. While particular embodiments of the invention have been described, it is not intended that the invention be limited thereto, as it is intended that the invention be as broad in scope as the art will allow and that the specification be read likewise. Thus, while particular downhole tools and analysis techniques have been disclosed for characterizing properties of the reservoir fluid and surrounding formation, it will be appreciated that other tools and analysis techniques could be used as well. Moreover, the methodology described herein is not limited to stations in the same wellbore. For example, measurements from samples from different wells can be analyzed as described herein for testing for lateral connectivity. In addition, the workflow as described herein can be modified. It will therefore be appreciated by those skilled in the art that yet other modifications could be made to the provided invention without deviating from its scope as claimed.

What is claimed is:

1. A method of characterizing a petroleum sample that includes a heavy fraction having at least a plurality of polar compounds, comprising:
a) ionizing the polar compounds in the petroleum sample; and
b) measuring properties of the ionized polar compounds using an orbitrap mass spectrometer comprising an electrostatic ion trap mass analyzer that employs an outer barrel-like electrode and a coaxial inner spindle-like electrode that form an electric field with quadro-logarithmic distributions, the petroleum sample characterized, at least in part, by the measured properties.

2. A method according to claim 1, wherein the measured properties are related to heteroatom class distributions with respect to the petroleum sample.

3. A method according to claim 2, wherein the heteroatom class distributions correspond to a predetermined set of heteroatoms contained in the heavy fraction of the petroleum sample.

4. A method according to claim 3, wherein the predetermined set of heteroatoms consists of heteroatoms selected from the group consisting of nitrogen, oxygen, and sulphur.

5. A method according to claim 3, wherein the measured properties include an indication of the relative abundance of compounds that contain the predetermined set of heteroatoms.

6. A method according to claim 1, wherein the polar compounds are ionized using electrospray ionization (ESI).

7. A method according to claim 6, wherein ESI produces positively and negatively charged ions of the polar compounds, and only properties of the negatively charged ions of the polar compounds are characterized using the orbitrap mass spectrometer.

8. A method according to claim 6, wherein ESI produces positively and negatively charged ions of the polar compounds, and each of the negatively and positively charged ions of the polar compounds are characterized separately with the orbitrap mass spectrometer.

9. A method according to claim 6, wherein ESI produces positively and negatively charged ions of the polar compounds, and the positively charged ions of the polar compounds are characterized using the orbitrap mass spectrometer.

10. A method according to claim 1, wherein the sample contains non-polar compounds and the non-polar compounds are not ionized.

11. A method according to claim 1, further comprising:
(c) measuring properties of the petroleum sample with a higher resolution compositional analyzer as compared to the orbitrap mass spectrometer of (b).

12. A method according to claim 11, wherein the higher resolution compositional analyzer is a Fourier transform ion cyclotron resonance mass spectrometer (FTICR-MS).

13. A method according to claim 11, wherein the higher resolution compositional analyzer is selected from the group including an X-ray absorption near edge spectrometer (XANES), a carbon X-ray Raman spectrometer (XRS), and a nuclear magnetic resonance spectrometer (NMR).

14. A method according to claim 1, further comprising:
(c) determining whether a higher resolution compositional analysis of the petroleum sample is justified based on the properties measured in (b); and
(d) performing a higher resolution compositional analysis of the petroleum sample based on the determining of (c).

15. A method according to claim 14, wherein the higher resolution compositional analysis of the petroleum sample is determined to be justified when greater than one percent of the peaks with intensity above a threshold for a heteroatoms class distribution are poorly resolved.

16. A method according to claim 14, wherein the higher resolution compositional analysis of the petroleum sample is determined to be justified when greater than three percent of the peaks with intensity above a threshold for a heteroatoms class distribution are poorly resolved.

17. A method according to claim 14, wherein the higher resolution compositional analysis of the petroleum sample is determined to be justified when greater than ten percent of the peaks with intensity above a threshold for a heteroatoms class distribution are poorly resolved.

18. A method according to claim 14, wherein:
multiple petroleum samples are characterized, and a heteroatoms class distribution with respect to each sample forms a fingerprint for such petroleum sample; and
in the event that at least two fingerprints match, then higher resolution compositional analysis of corresponding petroleum samples is determined to be justified for at least one, but fewer than all, of the petroleum samples having matching fingerprints.

19. A method for characterizing a hydrocarbon sample from a reservoir of interest traversed by a wellbore, the hydrocarbon sample having a heavy fraction having at least a plurality of polar compounds, the method comprising:
a) for at least one location with the wellbore, performing downhole fluid sampling operations at the location within the wellbore to collect the hydrocarbon sample at the location; and
b) first characterizing the hydrocarbon sample by,
i) ionizing the polar compounds in the hydrocarbon sample, and
ii) measuring properties of the ionized polar compounds using an orbitrap mass spectrometer comprising an electrostatic ion trap mass analyzer that employs an outer barrel-like electrode and a coaxial inner spindle-like electrode that form an electric field with quadro-logarithmic distributions.

20. A method according to claim 19, wherein the first characterizing includes defining properties of the hydrocarbon sample related to heteroatom class distribution.

21. A method according to claim 20, wherein the heteroatom class distributions correspond to a predetermined set of heteroatoms contained in the heavy fraction of the hydrocarbon sample.

22. A method according to claim 21, wherein the predetermined set of heteroatoms consist of heteroatoms selected from the group consisting of nitrogen, oxygen, and sulphur.

23. A method according to claim 21, wherein the measured properties include an indication of the relative abundance of compounds that contain the predetermined set of heteroatoms.

24. A method according to claim 19, wherein the first characterizing includes ionizing the polar compounds with electrospray ionization (ESI).

25. A method according to claim 19, further comprising:
(c) second characterizing the sample by measuring properties of the hydrocarbon sample with a higher resolution compositional analyzer as compared to the orbitrap mass spectrometer of (b).

26. A method according to claim 25, wherein the higher resolution compositional analyzer comprises a Fourier transform ion cyclotron resonance mass spectrometer (FTICR-MS).

27. A method according to claim 19, wherein:
downhole fluid sampling is performed at a plurality of locations within the wellbore such that a plurality of hydrocarbon samples is collected,
each of the hydrocarbon samples is subjected to the first characterizing, and
at least one of the hydrocarbon samples is subject to second characterizing by measuring properties of the least one hydrocarbon sample with a higher resolution compositional analyzer as compared to the orbitrap mass spectrometer of (b).

28. A method according to claim 27, wherein:
the first characterizing derives a heteroatom class distribution for each respective hydrocarbon sample, the heteroatom class distribution forming a fingerprint for the respective hydrocarbon sample; and
in the event that at least two fingerprints match, then higher resolution compositional analysis of corresponding hydrocarbon samples is determined to be justified for at least one, but fewer than all, of the hydrocarbon samples having matching fingerprints.

29. A method according to claim 19, further comprising prior to the first characterizing, verifying the sample as being representative of downhole reservoir fluids.

30. A method according to claim 19, further comprising prior to the first characterizing, verifying the chain of custody of the sample.
